(19) United States
(12) Patent Application Publication
(10) Pub. No.: US 2019/0124789 A1
(43) Pub. Date: Apr. 25, 2019

(54) ELECTRONIC DEVICE WITH ADJUSTING MODULE FOR HEAT DISSIPATION

(71) Applicant: HONGFUJIN PRECISION ELECTRONICS (TIANJIN) CO.,LTD., Tianjin (CN)

(72) Inventors: Kuan-Chin Yu, New Taipei (TW); Tung-Ho Shih, New Taipei (TW)

(21) Appl. No.: 15/832,605

(22) Filed: Dec. 5, 2017

(30) Foreign Application Priority Data
Oct. 23, 2017 (CN) 201710994528.9

(51) Int. Cl. H05K 7/20

(52) U.S. Cl. CPC H05K 7/20181; G06F 1/20

(57) ABSTRACT

An adjusting module for dissipating heat from an electronic device includes a blade, a motor, and a reset component. The motor comprises a shaft and the shaft is configured to rotate the blade. The reset component is configured to set the blade in a first position when the motor is not working, allowing maximum through flow of air. When the motor is working, the shaft is rotated for dissipating heat from the electronic device.

### FIELD

The subject matter herein generally relates to adjusting modules for adjusting airflow through electronic devices.

### BACKGROUND

A personal computer or server generates a lot of heat during operation. A fan is usually used to dissipate the heat, and an adjusting module is provided to adjust air to flow through the fan.

### BRIEF DESCRIPTION OF THE DRAWINGS

Implementations of the present technology will now be described, by way of example only, with reference to the attached figures.

FIG. 1 is an isometric view of an embodiment of an electronic device, the electronic device comprising an adjusting module with a blade.

FIG. 2 is an exploded and isometric view of the adjusting module of FIG. 1.

FIG. 3 is a cross-sectional view of the adjusting module of FIG. 1 along a line III-III, and shows the blade in a first position.

FIG. 4 is similar to FIG. 3, but shows the blade in a second position.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale and the proportions of certain parts may be exaggerated to better illustrate details and features of the present disclosure. It should be noted that references to “an” or “one” embodiment in this disclosure are not necessarily to the same embodiment, and such references mean “at least one”.

Several definitions that apply throughout this disclosure will now be presented. The term “comprising,” when utilized, means “including, but not necessarily limited to”; it specifically indicates open-ended inclusion or membership in the so-described combination, group, series, and the like.

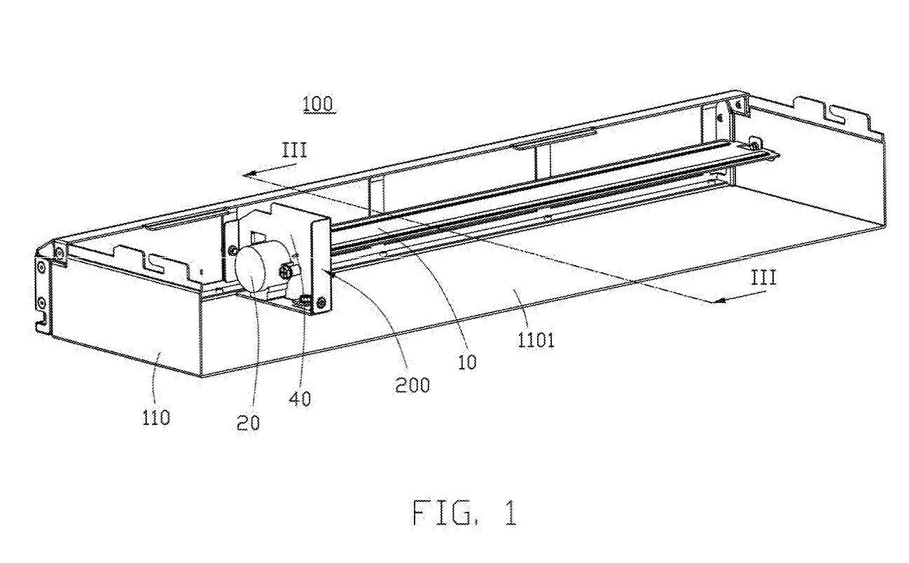

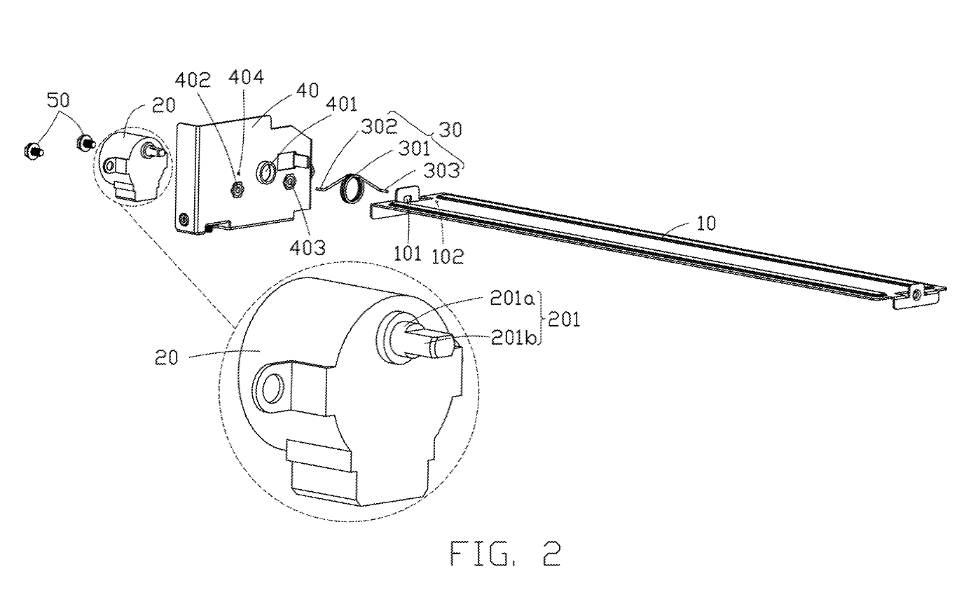

FIGS. 1 and 2 illustrate an electronic device 100 in accordance with an embodiment. The electronic device 100 can be a server, a personal computer, etc, and can comprise a housing 110 and an adjusting module 200. The adjusting module 200 can be installed in the housing 110, and can guide airflow through the housing 110.

The adjusting module 200 can comprise a motor 20 secured in the housing 110, a blade 10 configured to be rotated by the motor 20, and a reset component 30. The reset component 30 is configured to set the blade in a first position when the motor is not working.

The motor 20 can comprise a shaft 201. The shaft 201 can be rotated by the motor 20.

The reset component 30 can comprise a body 301, a first pin 302, and a second pin 303.

In one embodiment, the body 301 is installed on the shaft 201, the first pin 302 is configured to be secured to the housing 110 and the second pin 303 is configured to be secured to the blade 10.

When the motor 20 is in working, the blade 10 is rotated by the motor 20 with the shaft 201. The reset component 30 is resiliently deformed. The first pin 302 and the second pin 303 can press against the housing 110 and the blade 10.

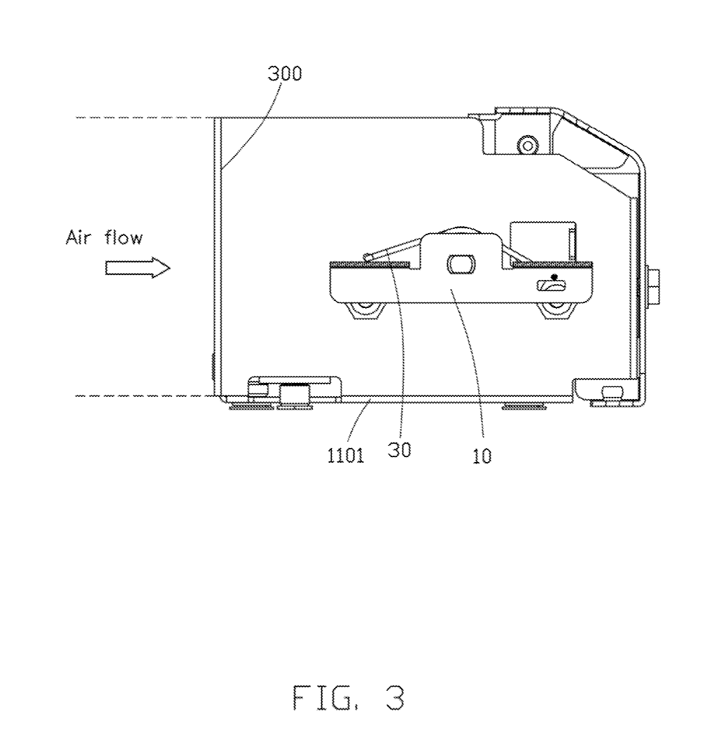

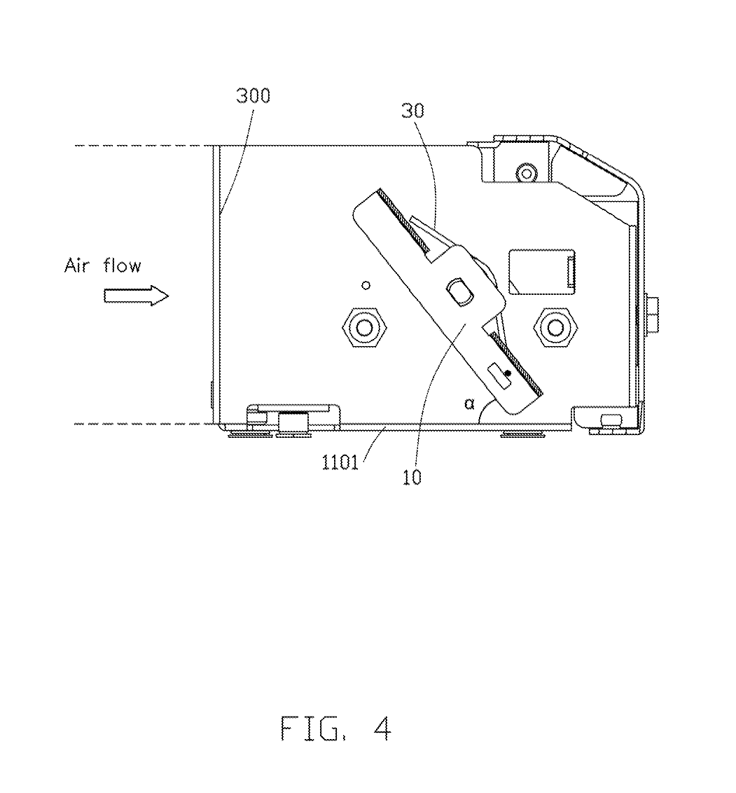

When the motor 20 is not working and the blade 10 is stopped in a second position (shown in FIG. 4), the reset component 30 can rebound to rotate the blade 10 from the second position to the first position (shown in FIG. 3).

In one embodiment, when the blade 10 is in the first position, a maximum airflow can pass through the blade 10. The electronic device 100 therefore retains good efficiency for heat dissipation.

In one embodiment, the adjusting module 200 can further comprise a mounting plate 40. The motor 20 can be fixed on the mounting plate 40 by at least one or more locking members 50. The locking members 50 may be screws, rivets, and so on. The mounting plate 40 defines a first through hole 401, a second through hole 402, a third through hole 403, and a fourth through hole 404.

The blade 10 can defines a fifth through hole 101 and a sixth through hole 102. The first pin 302 of the reset component 30 is secured in the fourth through hole 404. The second pin 303 of the reset component 30 is secured in the sixth through hole 102.

The shaft 201 passes through the first through hole 401 and the fifth through hole 101. The two locking members 50 are locked in the second through hole 402 and the third through hole 403 to secure the motor 20 to the mounting plate 40.

The shaft 201 comprises a first shaft part 201a and a second shaft part 201b. A shape of the first shaft part 201a is different from a shape of the second shaft part 201b. A cross section of the first shaft part 201a is matched with the first through hole 401, and a cross section of the second shaft part 201b is matched with the fifth through hole 101.

In one embodiment, the shape of the first shaft part 201a can be cylindrical, and the shape of the second shaft part 201b can be cuboid. The first through hole 401 can be circular, and the fifth through hole 101 can be rectangular.

In one embodiment, the reset component 30 can be a torsion spring.

In one embodiment, the adjusting module 200 can comprise two or more blades 10, and the reset component 30 can comprise two or more torsion springs. When the motor 20 is not working, one or more torsion springs can rotate the blades 10 to the first position.

Referring to FIG. 3, the blade 10 is located at the first position. The electronic device 100 comprises an air inlet 300. When the blade 10 is located at the first position, the blade 10 is parallel to a bottom surface 1101 of the housing 110. When the reset component 30 rotates the blade 10 to the first position, the electronic device 100 has the maximum through flow of air.

Referring to FIG. 4, the blade 10 is located at a second position, the blade 10 causes an obstruction to the air inlet 300. When the blade 10 is rotated to the second position, an angle α between the blade 10 and the bottom surface 1101 of the housing 110 is formed. The blade 10 is not parallel to the bottom surface 1101 of the housing 110. An airflow of the second position is less than the airflow of the first position.

The embodiments shown and described above are only examples. Many such details are neither shown nor described. Even though numerous characteristics and advantages of the present technology have been set forth in the foregoing description, together with details of the structure and function of the present disclosure, the disclosure is illustrative only, and changes may be made in the detail, including in matters of shape, size, and arrangement of the parts within the principles of the present disclosure, up to and including the full extent established by the broad general meaning of the terms used in the claims. It will therefore be appreciated that the embodiments described above may be modified within the scope of the claims.

What is claimed is:

1. An electronic device, comprising:
a blade;
a motor comprising a shaft and the shaft; and
a reset component engaged with the blade;
wherein the motor rotates the blade through the shaft, when the motor is not working, the reset component rotates the blade to a first position.

2. The electronic device of claim 1, further comprising a mounting plate, wherein the motor is fixed on the mounting plate by one or more locking members; and the reset component is stalled on the shaft.

3. The electronic device of claim 2, wherein the mounting plate defines a first through hole, a second through hole, and a third through hole; the blade defines a fourth through hole; the shaft passes through the first through hole and the fourth through hole to rotate the blade; and the one or more locking members are configured to fix the motor on the mounting plate through the second through hole and the third through hole.

4. The electronic device of claim 3, wherein the shaft comprises a first shaft part and a second shaft part; a shape of the first shaft part is different from a shape of the second shaft part; and a cross section of the first shaft part is matched with the first through hole, and a cross section of the second shaft part is matched with the fourth through hole.

5. The electronic device of claim 4, wherein the shape of the first shaft part is cylindrical, the shape of the second shaft part is cuboid, the first through hole is circular, and the fourth through hole is rectangular.

6. The electronic device of claim 3, wherein the reset component comprises a body, a first pin, and a second pin; the body is installed on the shaft, the blade further defines a fifth through hole, the mounting plate further defines a sixth through hole, the first pin is secured in the fifth through hole, and the second pin is secured in the sixth through hole.

7. The electronic device of claim 1, wherein the reset component is a torsion spring; when the motor is working, the motor defines a first energizing force; when the motor is not working, the motor defines a second energizing force; and a twisting force of the torsion spring is greater than the second energizing force and the twisting force of the torsion spring is less than the first energizing force.

8. The electronic device of claim 1, wherein the blade, the motor, and the reset component are installed in a housing; and when the blade is located at the first position, the blade is parallel to a bottom surface of the housing.

9. The electronic device of claim 8, wherein when the motor is working, the motor rotates the blade beginning at the first position; and when the blade is rotated at a second position, an angle between the blade and the bottom surface of the housing is formed.

10. An electronic device, comprising:
a housing; and
an adjusting module installed in the housing, the adjusting module comprising:
a blade;
a motor comprising a shaft and the shaft; and
a reset component engaged with the blade;
wherein the motor rotates the blade through the shaft, when the motor is not working, the reset component rotates the blade to a first position.

11. The electronic device of claim 10, wherein the adjusting module further comprises a mounting plate, the motor is fixed on the mounting plate by one or more locking members; and the reset component is stalled on the shaft.

12. The electronic device of claim 11, wherein the mounting plate defines a first through hole, a second through hole, and a third through hole; the blade defines a fourth through hole; the shaft passes through the first through hole and the fourth through hole rotate the blade; and the one or more locking members are configured to fix the motor on the mounting plate through the second through hole and the third through hole.

13. The electronic device of claim 12, wherein the shaft comprises a first shaft part and a second shaft part; a shape of the first shaft part is different from a shape of the second shaft part; and a cross section of the first shaft part is matched with the first through hole, and a cross section of the second shaft part is matched with the fourth through hole.

14. The electronic device of claim 13, wherein the shape of the first shaft part is cylindrical and the shape of the second shaft part is cuboid, the first through hole is circular and the fourth through hole is rectangular.

15. The electronic device of claim 12, wherein the reset component comprises a body, a first pin, and a second pin, the body is installed on the shaft, the blade further defines a fifth through hole, the mounting plate further defines a sixth through hole, the first pin is secured in the fifth through hole, and the second pin is secured in the sixth through hole.

16. The electronic device of claim 10, wherein the reset component is a torsion spring; when the motor is working, the motor defines a first energizing force; when the motor is not working, the motor defines a second energizing force; and a twisting force of the torsion spring is greater than the second energizing force and the twisting force of the torsion spring is less than the first energizing force.

17. The electronic device of claim 15, wherein when the blade is located at the first position, the blade is parallel to a bottom surface of the housing.

18. The electronic device of claim 10, wherein when the motor is working, the motor rotates the blade beginning at the first position; and when the blade is rotated at a second position, an angle between the blade and the bottom surface of the housing is formed.
